(19) United States
(12) Patent Application Publication
(10) Pub. No.: US 2022/0186762 A1
(43) Pub. Date: Jun. 16, 2022

(54) ELECTRICAL SHEET METAL PACKS FOR ELECTRIC MOTORS OR GENERATORS

(71) Applicant: SWD AG, Densbueren (CH)

(72) Inventor: Georg SENN, Densbueren (CH)

(21) Appl. No.: 17/689,477

(22) Filed: Mar. 8, 2022

(51) Int. Cl. F16B 11/00; F16B 5/08; H05K 13/04

(52) U.S. Cl. CPC F16B 11/006; H05K 13/0469; F16B 5/08

(57) ABSTRACT

In a method for manufacturing metal bodies, e.g., stators for electric motors, a stack of sheet metal parts (14), which have thermally-curable adhesive layers provided therebetween, is guided over a mounting mandrel (11) of a tool, and/or is held by an external fixture (25). The stack is then heated to cure the adhesive layers while applying pressure thereto, thereby forming the metal body. In the course of the method, at least one of the applied pressure, the temperature of the stack, and/or the height of the stack is measured. A prescribed height of the stack is adjusted by performing a temperature-pressure control. The present system and method enables efficient and precise production of stators, is self-learning and enables the measurement, regulation and recording of all manufacturing parameters in the course of the manufacture of each individual stator. In particular, all manufacturing parameters can retrospectively be associated with an individual stator.

### TECHNICAL FIELD

The invention relates to a method for the manufacture of metal bodies, for the production of electrical sheet metal packs for use in electric motors, that includes: stamping and forming a stack made up of electrical metal sheets in a baking tool, wherein one or both sheet metal surfaces are provided with thermally-curable adhesive layers, and heating the stack so as to cure the adhesive layers and so as to form the metal body, wherein pressure is applied to the stack in the course of the heating procedure.

### BACKGROUND ART

The demand for electric motors, generators, and electric machines in general, is constantly increasing, amongst other causes as a result of the proliferation of electric cars and hybrid cars. For this reason, stators and rotors have to be manufactured in large numbers, and with high precision, while at the same time keeping production costs as low as possible and saving as much material as possible in the manufacture. One technology that is used here is the production of electrical sheet metal packs from individual magnetic lamellae.

US 2017/0012508 A1 relates to a method for the manufacture of metal bodies, for the production of primary segmented stator electrical sheet metal packs for use in electric motors or generators, with the steps of stamping, and the forming of a stack of electrical sheet metal in a cavity of a tool, wherein thermally-cured adhesive layers are provided between the sheet metal parts, and heating of the stack to cure the adhesive layers and form the metal body, wherein pressure is applied to the stack in the course of the heating procedure.

The current methods for the packing of welded and baked/adhesively bonded packs need to be optimised and improved economically.

### SUMMARY

It is the object of the invention to create a method appropriate to the technical field mentioned in the introduction, by which metal bodies, in particular a pack of lamellae, can be manufactured for use in electric motors in a particularly cost-effective, efficient manner, in an optimised process.

The achievement of the object is defined by the features of Claim 1. In accordance with the invention, at least one of the following parameters is measured and/or controlled in the course of the method:
applied pressure,
temperature of the stack,
height of the stack (iron length).

Furthermore, in accordance with the invention, a prescribed height of the stack is adjusted by the application of a temperature-pressure control. That is to say, the temperature and pressure can be controlled such that the stack reaches a predetermined height (this is not mandatory). This can be achieved by varying only the pressure, varying only the time, varying only the temperature or, more preferably, by varying the temperature and the time and the pressure. This makes it possible to adjust the parameters in the course of the heating procedure if the stack height alters. The inventive EPS®, EPS-Einplatzpaketiersystem®, [EPS-single-station packing system] or the Einplatzpaketiersystem® [single-station packing system], can accommodate fluctuations in the material properties by altering the parameters in the course of the method.

In the manufacturing process, a stack is first formed in a tool from a plurality of sheet metal parts. Thermally-cured adhesive layers are provided between the sheet metal parts. These cover a substantial part of the surface of the sheet metal piece, such that a permanent, two-dimensional bond can be formed between the two surfaces of the sheet metal parts lying on top of one another. However, it is not mandatory that the adhesive layers extend over the entire surface of the sheet metal parts. The sheet metal parts are heated so as to cure these adhesive layers, and thus to form the sheet metal stack body.

The inventive method can be operated such that it is directly linked with the stamping process for the stamping of the individual lamellae. That is to say, the individual lamellae are stamped in the usual manner in a linked production line. The loose individual lamellae are packed, that is to say, stacked, and filled into baking tools.

In one variant of the method, the individual lamellae are already initially adhesively bonded together in the stamping tool or initially fixed by means of (baking-) packing nubs (stamp packing). This means that instead of loose individual sheets, stacks that are already packed can be removed, which simplifies the handling of the lamellae.

For the determination of the correct number of lamellae, they are counted, weighed, and/or pressed and measured under a press with a force/displacement measuring system, or only with force. It is also conceivable to combine a plurality of methods and, in particular, to take into account other parameters, such as the shrinkage to be anticipated as a result of the baking.

It is possible to combine different sheet metal types or sequences, or to twist sheets or sub-stacks relative to each other. These pre-packed stacks are then manually or automatically filled into precision baking tools. In what follows the electrical sheet metal pack is then baked on the baking tool, typically for a relatively short time, to form a solid electrical sheet metal pack. This is followed by removal from the baking tool.

The preferred field of application of the inventive method is in the manufacture of stators for electric motors, but it can also be applied to other forms of electrical sheet metal packs. The stators are usually the non-moving parts in an electric motor, while the rotor is designed to rotate relative to the stator.

However, the invention can also be used for the manufacture of components of other dynamoelectric machines, in particular magnetic cores made up from metal sheets for transformers, but also for the manufacture of sensors, actuators, etc.

The baking tool can have any desired shape, and is designed on the basis of the geometry of the lamellae. If the lamellae, or sheet metal lamellae, have an opening, the baking tool can simply comprise a support plate with a mounting mandrel, upon which the lamellae can be stacked. In this case, the mounting mandrel can hold the lamellae stationary, and preferably also relative to each other in the desired position, so that a cavity that at least partially encloses the lamellae can be dispensed with.

As an alternative, or in addition, to the mounting mandrel, a cavity can be provided, which at least partially encloses the lamellae on the outside. It is clear to the person skilled in the art that the baking tool can thus have essentially any desired shape. The design of the baking tool depends on the sheet geometry and its method of fixture.

The sheet metal lamellae are stamped in a manner of known art, and are conveyed out of the stamping press in a manner of known art, either individually or as sub-packs. Pre-packing in a manner of known art, with measurement of the stack height, or the twisting of sub-packs or individual lamellae, is also useful, depending on the requirements. The sheet metal parts are then inserted into the baking tools, either manually or automatically (e.g. by means of a robot), as individual lamellae, sub-stacks or entire stacks.

Alternatively, the sheet metal parts can also be formed in a manner other than by stamping, for example by laser cutting, or by cutting them out of larger sheet metal parts.

The stack height is preferably measured by means of a stamp that presses onto the pack of lamellae. On the one hand, the stamp serves to hold the sheet metal parts in position during the heating phase, that is to say, to exert pressure, and on the other hand, it serves to measure the stack height and, if required, but not necessarily, to regulate it. The stack height can, on the one hand, be measured by way of a distance of travel of the stamp, but it can also be measured by way of the pressure of the stamp, by way of a conductivity between stamp and baking tool, or by way of an elasticity of the stack, etc. Thus, for example, the pressure can be increased with the stamp during the heating procedure, so as to compensate for any expansion of the stack. However, the pressure can also be varied during the heating phase such that the properties of the adhesive layer are optimally taken into account, in order to achieve an efficient and precise curing.

The stack is preferably heated, in particular baked, in the stacking and packing unit, so as to form the pack of lamellae. This activates the adhesive, so that the individual sheet metal parts are held together.

Alternatively, the heating procedure can be omitted, in particular if the adhesive does not need to be cured under heat, or if the bonds are made by welding.

The stack is preferably subjected to a baking process in the stacking and packing unit, wherein the stack is heated by way of any desired fluid, for example an oil, water, air, etc., or directly or indirectly electromagnetically, or by way of any other technique known to the person skilled in the art, for purposes of heat transfer, and is subsequently cooled, in particular actively, whereby a metal body is obtained. For this purpose, the device preferably comprises a heating device, in particular a supply of fluids, or a directly or indirectly directed electromagnetic heating device, or any other device known to the person skilled in the art for the introduction of heat, and a cooling device.

Direct heating of the stack has the advantage that the process can be controlled very precisely. Furthermore, intervention into the heating process can be made with a short time delay, especially since the heating acts directly, and typically has a short reaction time. Furthermore, this enables a particularly uniform heating of the individual sheet metal parts of the stack to be achieved.

The heat transfer (that is to say, the heating or cooling) preferably takes place as a function of the component geometry from the inside, in particular by way of the mounting mandrel of the baking tool (see above), or from the outside, or from both the inside and the outside. If heat transfer takes place from both the inside and the outside, the process can be optimised by suitable control of the respective heat supplied from the inside and the outside. This means, for example, that a higher temperature can be selected for heating the lamellae pack on the mounting mandrel than on the outside, or vice versa. Furthermore, the heat transfer can also take place alternately by way of the mounting mandrel and the outside. Further variants are known to the person skilled in the art.

By the use of active cooling, the manufacturing method can be designed to be particularly efficient, or a cycle time can be kept low, in particular if the metal body should not be, or cannot be, removed from the baking tool at an elevated temperature. This can be the case if the adhesive bonding in the hot metal body is not strong enough, or if the metal body can be more easily removed from the baking tool when it has been cooled. The cooling procedure is preferably carried out by introducing a cooling fluid such as cooling air, cooling oil, water, or other techniques for heat extraction.

In variants, the stack can also be heated in another manner, for example by using heating cartridges. The cooling process can also be carried out in a different manner, or the cooling of the lamellae stacks can be omitted.

In variants, the stack height can also be measured by other means. Alternatively, the measurement of the stack height can also be omitted.

Preferably, method parameters are adjusted individually for each stack, in particular one method parameter is altered in the course of the baking process from:

a) a power supply for the heating of the stack,

b) a holding time at a temperature after the heating of the stack,

c) a pressure at which a stack is held in the course of the heating procedure.

The adjustment of the method parameters serves in particular to reduce a manufacturing time and/or to increase the precision for a metal body, and can be carried out dynamically in the course of the heating/cooling procedure, and is not limited to the method parameters cited above.

In contrast to the methods of known art, the height is thereby not only measured, but also actively regulated on the basis of the current measured values. This means that the parameters can be optimised in the course of the method. In particular, the pressure with which the stack is pressed can be increased in the course of the heating procedure, for example. Also, the temperatures can follow any desired curve, and the times can be varied. The metal body is thus formed in a solid and precise manner.

In a further advantageous configuration of the method, the measurement data of the stack height and the temperatures are stored, on the one hand so as to document the manufacturing process, and on the other hand so as to be able to optimise the method further. Quality features can also be determined, stored and evaluated.

In variants, an adjustment of method parameters in the course of the method can also be dispensed with.

The method is preferably executed fully automatically and continuously, and is linked with the stamping process. The stamping of the sheets, and thus the stacking of the sheets, if required the pre-packing of the stacks, the levelling and alignment of the stacks, as well as the heating and cooling of the stacks, and finally the removal of the metal body from the baking tool, preferably takes place in a continuous process. In short, the production line is carried out as a continuous process from the unstamped sheet metal, which is delivered in rolls, for example, to the finished metal body.

Here it does not matter whether, for example, the sheet metal stacks, or other intermediate products, are manufactured in a first step, and the sheet metal body is finished in a second, separate step. This means that individual steps in the operation can also be executed in a locally separated manner. It would also be conceivable to manufacture the individual sheets in advance and supply them separately to the system. In particular, this would allow complex sequences of lamellae to be bonded together to form a pack.

The individual method parameters are preferably stored for each metal body manufactured. In conjunction with a labelling of the packs of lamellae, it is thereby possible to trace back to how a particular metal body was manufactured. This means that subsequent tests on the metal bodies can be reduced or avoided altogether, whereby the method as a whole can be designed to be more efficient. The measured method parameters can be automatically compared with a respective design range, so that rejects can be efficiently detected and sorted out. Based on the stored values and random samples, the method parameters can also be optimised particularly efficiently. Furthermore, the method parameters can be automatically and dynamically adjusted on the basis of the stored values of the immediately preceding manufacture of one or a plurality of metal bodies.

In variants, the individual recording of the method parameters can also be dispensed with. For example, it may also be sufficient to store a moving average value of the method parameters over a plurality of metal bodies.

The stamping unit, the stacking and packing unit, and the ejection unit, are preferably coordinated with each other by means of a computer unit. This allows, for example, the throughput of the stamping unit to be matched to the throughput of the stacking and packing unit, in order to avoid a logjam upstream of the stacking and packing unit. Coordination can be further provided such that a plurality of units are controlled so as to achieve an optimal throughput. Furthermore, in the event of overcapacity, for example, a plurality of stacking and packing units can be controlled such that a cooling procedure takes place passively in order to save energy. Further optimisation possibilities are also known to the person skilled in the art.

In variants, the stamping unit, and the stacking and packing unit, do not necessarily have to be coordinated by way of a computer. It can be sufficient to adjust the throughput to that of the station/unit with the smallest capacity.

A device or a production line for the execution of the method comprises a pre-packing station, and a stacking and packing unit, wherein the stacking and packing unit comprises a plurality of, preferably identical, stacking and packing units. This design is of particular advantage because the stamping device typically has a high capacity compared to a stacking and packing unit, that is to say, more stacks can be created per unit of time with a stamping device than can be packed by means of a stacking and packing unit. Depending on the throughput and functions (stacking of different sheets, twisting and orientation of the sheets, etc.), the pre-packing station is required in a single or a multiple embodiment. The stacking and packing unit becomes the speed-determining step in the method, while the stamping unit with a single stamping module is typically under-utilised. With a stacking and packing unit with a plurality of stations, the capacity of the stamping unit can be fully utilised, and thus the method can be optimised.

Alternatively, the stacking and packing unit can be designed in such a way that a plurality of baking tools with the stacks can be processed at the same time in the same station. Furthermore, a plurality of stacks can be processed at the same time in one baking tool.

The device preferably comprises automation for purposes of loading the stacking and packing unit and for transfer.

In principle, individual or a plurality of processing stations can be integrated. Alternatively, loading and transfer can also be carried out manually.

The method enables fully automated production, and thus highly rational, actionable and reproducible production. The production facility is characterised by a high degree of modularity, flexibility, self-monitoring and self-optimisation, as well as by the ability to document the manufacturing process. The device can therefore undertake production in a completely autonomous manner, and does not require any specific know-how on the part of the user. By virtue of the high level of automation, selection of an installation site for the production facility can be flexible. In particular, the possibility exists of decentralised monitoring of the functioning of the production facility.

Depending on the required production volume, the stamping speed can be varied or the number of stacking and packing units can be increased. This means that even small batches, or series start-ups, can be produced efficiently, and the production volume can be increased in an almost stepless manner. Very high cycle times can be achieved.

Further advantageous forms of embodiment and combinations of features of the invention result from the following detailed description and the total content of the patent claims.

### BRIEF DESCRIPTION OF THE DRAWINGS

FIG. 1 shows a schematic representation of a stacking and packing unit, in which the sheet metal parts are held by way of a mounting mandrel; and

FIG. 2 shows a schematic representation of a stacking and packing unit, in which the sheet metal parts are held by way of a mounting mandrel and an external fixture.

In principle, the same parts are provided with the same reference symbols in the figures.

### DETAILED DESCRIPTION OF THE INVENTION

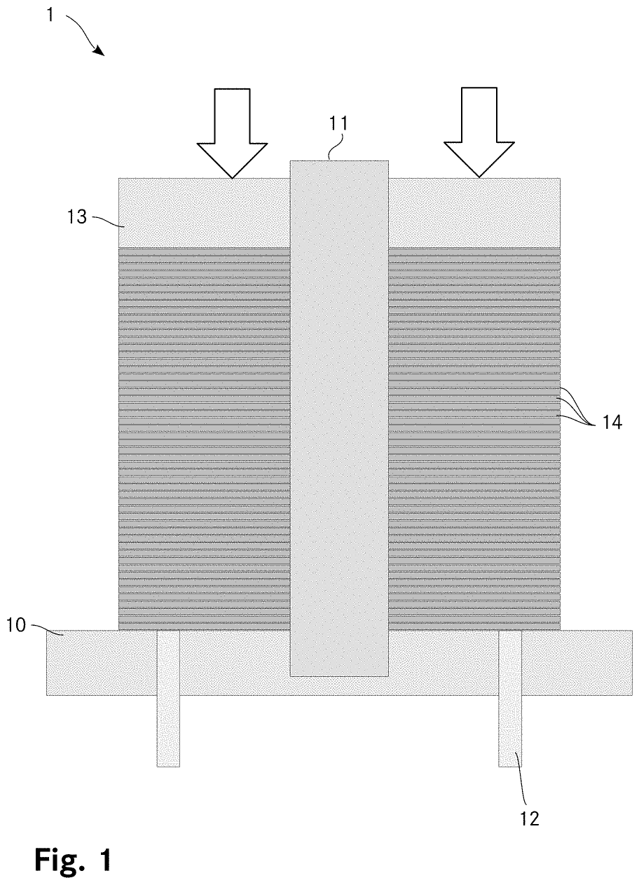

FIG. 1 shows a schematic representation of a stacking and packing unit 1, in which sheet metal parts 14 are bonded together to form a metal body. The stacking and packing unit 1 comprises a support plate 10 with a mounting mandrel 11, together with a stamp 13 for purposes of exerting a pressure on the stacked sheet metal parts 14. The sheet metal parts 14 are guided over the mounting mandrel 11, either in a pre-packed manner, or individually. The mounting mandrel 11 holds the sheet metal parts 14 in the desired position. The stamp 13 is now guided over the mounting mandrel 11, and pressure is applied onto the sheet metal parts 14. At the same time, the sheet metal parts are heated (see below) so as to create the metal body. The sheet metal parts 14 preferably take the form of sheet metal lamellae, which, as described above, are baked so as to become electrical sheet metal packs for electric motors, generators, and the like.

By way of the pressure, and/or the position (height) of the stamp, the stack height is, on the one hand, controlled and monitored, and is also regulated as required. In particular, in the course of the bonding of the sheet metal parts 14 into a metal body, corrective intervention in the active bonding method can be carried out on the basis of the measured values, for example by regulation of the temperature, the duration, or the stamp pressure. In this manner, an efficient production of metal bodies can be achieved.

Various technologies are of known art for the bonding of the individual sheet metal parts 14. In particular, the sheet metal parts 14 can be welded together or adhesively bonded. For example, an epoxy coating, in particular known as baking enamel, can be provided as the adhesive.

The individual sheet metal parts 14 are bonded together to form a metal body by means of a precisely controlled heating, holding, and cooling process, in the course of which the stack of sheet metal parts 14 is held under pressure by the stamp 13. In this phase, the adhesive between the individual sheet metal parts 14 can cross-link and thus be cured. The curing procedure takes place depending on the adhesive used, for example by means of a chemical reaction, the evaporation of a solvent, or the like.

Heating is preferably carried out by way of a fluid, such as water or an oil, or directly or indirectly electromagnetically or electrically, but can also be carried out by way of other devices known to the person skilled in the art. For example, heating can also be carried out by way of heating cartridges. The heating is recorded, and/or controlled, by way of sensors.

The cooling procedure is also preferably actively controlled, and is preferably carried out by way of a fluid, in particular with a cooling liquid or a cooling gas. However, other possibilities are also known to the person skilled in the art. The cooling is recorded, and/or controlled, by way of sensors.

The bonding procedure for each individual metal body is individually monitored and documented. This means that there is a fully documented manufacturing history for each individual product.

After the metal body is baked, it is ejected from the mould by way of ejectors 12. The ejectors 12 are designed in the form of pins, and can be pushed through the support plate 10, through openings from below. If necessary, the ejectors can also be dispensed with; other suitable techniques are also known to the person skilled in the art, for example the metal body can also be removed from the mould by means of compressed air, magnetic grippers, or other means. In a preferred form of embodiment, the device has a modular structure, so that a plurality of stacking and packing units 1 can be provided, which in particular are loaded by a single stamping unit.

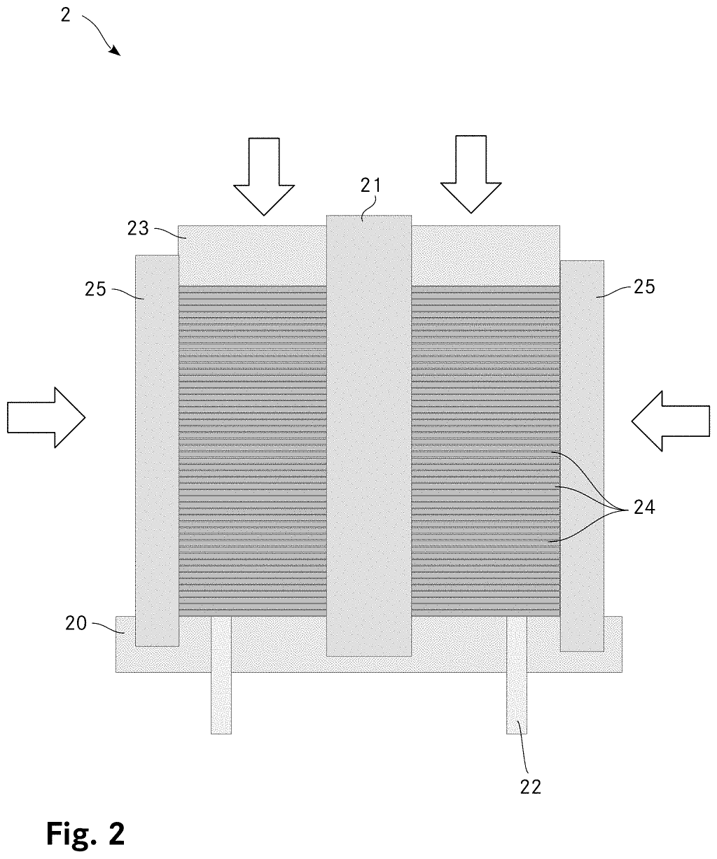

FIG. 2 shows a stacking and packing unit that is essentially analogous to that in FIG. 1, but the present stacking and packing unit 2 comprises, in addition to the mounting mandrel 21, an external fixture 25, by way of which the sheet metal parts 24 are held on their outside surfaces. In addition to, or as an alternative to, the mounting mandrel 21, heat or cold can be applied by way of the external fixture 25. It should be noted that in principle the mounting mandrel 21 can also be dispensed with in the form of embodiment shown in FIG. 2. After the baking procedure, the metal body is, here too, ejected by way of the ejector 22.

The transport from a stamping unit (not shown) to the stacking and packing unit 1 preferably takes place by way of an automation system (not shown), or a similar transport system, but can also be carried out manually.

By virtue of the high level of automation of the device, the processes and parameters can be tracked in a stable manner, and moreover a consistently high level of quality can be ensured.

In summary, in accordance with the invention a method is created for the manufacture of metal bodies, in particular electrical sheet metal packs for electric motors, which can efficiently, and essentially autonomously, manufacture metal bodies at a high quality and with a large throughput. The method is preferably self-learning, in that data from the production of the latest metal bodies are automatically used to optimise the method. Thus, a device for the execution of the method can be installed at a manufacturer without specific method and facility know-how. In particular, the facility can be set up and operated directly at the location at which the manufactured metal bodies are further processed.

I claim:

1. Method for the manufacture of metal bodies, in particular for the production of electrical sheet metal packs for use in electric motors, with the following steps:
a) formation of a stack from a plurality of sheet metal parts (14) in a tool (1), wherein, between the sheet metal parts (14), one or both sheet metal surface(s) are provided with thermally-cured adhesive layers, and
b) heating of the stack so as to cure the adhesive layers and to form the metal body,
c) wherein pressure is applied to the stack in the course of the heating procedure,
characterised in that:
d) the tool has a mounting mandrel (11) and/or an external fixture (25), over which the sheet metal parts (14) are pushed, either individually, or as a sheet metal parts pack formed from a plurality of sheet metal parts, so as to form a stack.

2. Method according to claim 1, characterised in that the stack of sheet metal parts comprises a plurality of sheet metal parts, initially adhesively bonded together into a stack or a sub-stack, and/or held by an external fixture (25).

3. Method according to claim 1, characterised in that the stack is welded together or baked so as to form the metal body.

4. Method according to claim 1, characterised in that the stack is subjected to a baking process, wherein the stack is heated by way of a fluid, or directly or indirectly, magnetically or electrically, and is subsequently cooled, in particular actively cooled, whereby a metal body is obtained.

5. Method according to claim 4, characterised in that the stack is heated from the outside, and/or by way of the mounting mandrel.

6. Method according to claim 1, characterised in that for each stack method parameters, in particular, in the course of the baking process, one method parameter from:
a) a power output for the heating of the stack (11),
b) a temperature curve for the heating of the stack (11),
c) a pressure, with which a stack is compressed in the course of the heating procedure,
is individually dynamically adjusted, in particular so as to reduce a manufacturing time for a metal body (12).

7. Device for the execution of a method according to claim 1, comprising a tool (1) with a mounting plate (10) and a mounting mandrel 11, and/or an external fixture, for the mounting of sheet metal parts (14).

8. Device according to claim 7, characterised in that the tool (1) comprises a heating device, in particular a heating device through which fluids flow, or which is directly or indirectly, electromagnetically or electrically heated, and a cooling device, with which in particular the mounting mandrel (11), and/or the external fixture (25), can be heated and/or cooled.
